(19) United States
(12) Patent Application Publication
(10) Pub. No.: US 2025/0284194 A1
(43) Pub. Date: Sep. 11, 2025

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Yaeun SEO, Suwon-si (KR); Eunmi KANG, Suwon-si (KR); Jimin KIM, Suwon-si (KR); Taegeun SEONG, Suwon-si (KR); Seung-Wook SHIN, Suwon-si (KR); Minyoung LEE, Suwon-si (KR); Chungheon LEE, Suwon-si (KR); Sumin JANG, Suwon-si (KR); Miyeon HAN, Suwon-si (KR)

(21) Appl. No.: 19/019,153

(22) Filed: Jan. 13, 2025

(30) Foreign Application Priority Data
Mar. 11, 2024 (KR) 10-2024-0034113

(51) Int. Cl. G03F 7/004; H01L 21/308; H01L 21/311

(52) U.S. Cl. CPC G03F 7/0045; G03F 7/0042; H01L 21/3081; H01L 21/31144

(57) ABSTRACT

A semiconductor photoresist composition and a method of forming patterns utilizing the semiconductor photoresist composition are provided. The semiconductor photoresist composition includes a Sn-containing organometallic compound, a carboxylic acid compound substituted with an O-containing heterocycle, and a solvent.

### CROSS-REFERENCE TO RELATED APPLICATION

The present application claims priority to and the benefit of Korean Patent Application No. 10-2024-0034113, filed on Mar. 11, 2024, in the Korean Intellectual Property Office, the entire content of which is incorporated herein by reference.

### BACKGROUND

### 1. Field

One or more embodiments of the present disclosure relates to a semiconductor photoresist composition and a method of forming patterns using the semiconductor photoresist composition.

### 2. Description of the Related Art

Extreme ultraviolet (EUV) lithography is recognized (paid attention to) as a critical (an essential) technology for the production of advanced semiconductor devices for the next generation. The EUV lithography is a pattern-forming technology utilizing an EUV ray having a wavelength of 13.5 nm as an exposure light source. According to the EUV lithography, an extremely fine pattern (e.g., less than or equal to 20 nm) may be formed in an exposure process during a manufacturing process of a semiconductor device.

The EUV lithography is realized through development of compatible photoresists which may be performed at a spatial resolution of less than or equal to 16 nm (i.e., compatible photoresists capable of facilitating a spatial resolution of 16 nm or smaller). Currently, efforts to satisfy insufficient specifications of comparable chemically amplified (CA) photoresists such as a resolution, a photospeed, and feature roughness (or also referred to as a line edge roughness or LER) for the next generation device are being made (to meet the inadequate criteria of comparable chemically amplified (CA) photoresists, including aspects such as resolution, photospeed, and feature roughness—also known as line edge roughness (LER)—for upcoming generation devices).

An intrinsic image blurring due to an acid catalyzed reaction in these polymer-type or kind photoresists limits a resolution in small feature sizes, which has been existed in electron beam (e-beam) lithography for a long time. The CA photoresists are designed for high sensitivity, but because their typical elemental makeups reduce light absorbance of the photoresists at a wavelength of 13.5 nm and thus decrease their sensitivity, the CA photoresists may partially have more difficulties under an EUV exposure.

In addition, the CA photoresists may have difficulties in the small feature sizes due to roughness issues, and line edge roughness (LER) of the CA photoresists experimentally turns out to be increased, as a photospeed is decreased partially due to an essence of acid catalyst processes. Accordingly, a novel high-performance photoresist is desired or required in a semiconductor industry because of these defects and problems of the CA photoresists.

In order to overcome the aforementioned drawbacks of the CA organic photosensitive composition, an inorganic photosensitive composition has been researched. The inorganic photosensitive composition is mainly utilized for negative tone patterning having resistance against removal by a developer composition due to chemical modification through nonchemical amplification mechanism. The inorganic composition contains an inorganic element having a higher EUV absorption rate than hydrocarbon and thus may secure sensitivity through the nonchemical amplification mechanism, and in addition, is less sensitive about a stochastic effect and thus suitable to have low line edge roughness and the small number of defects.

Inorganic photoresists based on peroxopolyacids of tungsten mixed with tungsten, niobium, titanium, and/or tantalum have been reported as radiation sensitive materials for patterning.

These materials are effective for patterning large pitches for bilayer configuration as far ultraviolet (deep UV), X-ray, and electron beam sources. More recently, when cationic hafnium metal oxide sulfate (HfSOx) materials along with a peroxo complexing agent has been utilized to image a 15 nm half-pitch (HP) through projection EUV exposure, impressive performance has been obtained. This system exhibits the highest performance of a non-CA photoresist and has a practicable photospeed near to a requirement for an EUV photoresist. However, the hafnium metal oxide sulfate material having the peroxo complexing agent has a few practical drawbacks. First, these materials are coated in a mixture of corrosive sulfuric acid/hydrogen peroxide and have insufficient shelf-life stability. Second, a structural change thereof for performance improvement as a composite mixture is not easy. Third, development should be performed in a tetramethylammonium hydroxide (TMAH) solution at an extremely high concentration of 25 wt % and/or the like.

Recently, to, e.g., address these issues, active research has been conducted as it is recognized that molecules containing tin have excellent or suitable absorption of extreme ultraviolet rays (i.e., tin-containing molecules exhibit superior absorption properties for extreme ultraviolet rays). As for an organotin polymer among them, alkyl ligands are dissociated by light absorption or secondary electrons produced, and thereby crosslinking with adjacent chains through oxo bonds, and thus enable the negative tone patterning which may not be removed by an organic developer. This organotin polymer exhibits greatly improved sensitivity as well as maintains a resolution and line edge roughness, but the patterning characteristics need to be additionally improved for commercial availability (i.e., its patterning attributes may require further refinement to be commercially viable).

### SUMMARY

One or more embodiments of the present disclosure are directed towards a semiconductor photoresist composition with excellent or suitable sensitivity and line edge roughness (LER) characteristics and improved sensitivity.

One or more embodiments of the present disclosure are directed towards a method of forming patterns utilizing the semiconductor photoresist composition.

Additional aspects will be set forth in part in the description which follows and, in part, will be apparent from the description, or may be learned by practice of the presented embodiments of the disclosure.

In one or more embodiments, a composition for a semiconductor photoresist may include a Sn-containing organometallic compound, a carboxylic acid compound substituted with an O-containing heterocycle, and/or a solvent.

In one or more embodiments, the method of forming patterns may include forming an etching-objective layer on a substrate, coating the semiconductor photoresist composition on the etching-objective layer to form a photoresist layer, patterning the photoresist layer to form a photoresist pattern, and etching the etching-objective layer utilizing the photoresist pattern as an etching mask.

According to one or more embodiments of the present disclosure, a semiconductor photoresist composition of the present disclosure may implement excellent or suitable sensitivity and excellent or suitable LER characteristics. That is, the semiconductor photoresist may be prepared by a relatively low corrosive and economic process without negative tone patterning and size limitation, and may enhance the commercial availability.

### BRIEF DESCRIPTION OF THE DRAWINGS

FIGS. 1A-1E are cross-sectional views for illustrating a method of forming patterns using a semiconductor photoresist composition according to one or more embodiments of the present disclosure.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

Hereinafter, referring to the drawings, embodiments are described in more detail. In the following description of disclosure, the well-suitable functions or constructions will not be described in order to clarify disclosure.

In order to clearly illustrate the present disclosure, the description and relationships are omitted, and throughout the disclosure, the same or similar configuration elements are designated by the same reference numerals. Also, because the size and thickness of each configuration shown in the drawing are arbitrarily shown for better understanding and ease of description, disclosure is not necessarily limited thereto.

In the drawings, the thickness of layers, films, panels, regions, and/or the like., are enlarged for clarity. In the drawings, the thickness of a part of layers or regions, and/or the like, is exaggerated for clarity. It will be understood that if (e.g., when) an element such as a layer, film, region, or substrate may be referred to as being “on” another element, it may be directly on the other element or intervening elements may also be present. In contrast, when an element is referred to as being “directly on” another element, there are no intervening elements present.

As utilized herein, “substituted” may refer to a replacement of a hydrogen atom by deuterium, a halogen, a hydroxyl group, a carboxyl group, a thiol group, a cyano group, a nitro group, —NRR′ (where R and R′ may each independently be hydrogen, a substituted or unsubstituted C1 to C30 saturation or unsaturated aliphatic hydrocarbon group, a substituted or unsubstituted C3 to C30 saturation or unsaturated alicyclic hydrocarbon group, and/or a substituted or unsubstituted C6 to C30 aromatic hydrocarbon group), —SiRR′R″ (where R, R′, and R″ may each independently be hydrogen, a substituted or unsubstituted C1 to C30 saturation or unsaturated aliphatic hydrocarbon group, a substituted or unsubstituted C3 to C30 saturation or unsaturated alicyclic hydrocarbon group, and/or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, and/or a (e.g., any suitable) combination thereof. “Unsubstituted” may refer to non-replacement of a hydrogen atom by another substituent and remaining of the hydrogen atom.

As utilized herein, if (e.g., when) a definition is not otherwise provided, “alkyl group” may refer to a linear or branched aliphatic hydrocarbon group. The alkyl group may be “saturated alkyl group” without any double bond or triple bond.

In one or more embodiments, the alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As utilized herein, if (e.g., when) a definition is not otherwise provided, “cycloalkyl group” may refer to a monovalent cyclic aliphatic hydrocarbon group.

In one or more embodiments, the cycloalkyl group may be a C3 to C8 cycloalkyl group, for example, a C3 to C7 cycloalkyl group, a C3 to C6 cycloalkyl group, a C3 to C5 cycloalkyl group, and/or a C3 to C4 cycloalkyl group. For example, the cycloalkyl group may be a cyclopropyl group, a cyclobutyl group, a cyclopentyl group, or a cyclohexyl group, but the present disclosure is not limited thereto.

As utilized herein, “aliphatic unsaturated organic group” may refer to a hydrocarbon group including a bond in which the bond between the carbon and carbon atom in the molecule is a double bond, a triple bond, and/or a (e.g., any suitable) combination thereof.

In one or more embodiments, the aliphatic unsaturated organic group may be a C2 to C8 aliphatic unsaturated organic group. For example, the aliphatic unsaturated organic group may be a C2 to C7 aliphatic unsaturated organic group, a C2 to C6 aliphatic unsaturated organic group, a C2 to C5 aliphatic unsaturated organic group, and/or a C2 to C4 aliphatic unsaturated organic group. For example, the C2 to C4 aliphatic unsaturated organic group may be a vinyl group, an ethynyl group, an allyl group, a 1-propenyl group, a 1-methyl-1-propenyl group, a 2-propenyl group, a 2-methyl-2-propenyl group, a 1-propynyl group, a 1-methyl-1 propynyl group, a 2-propynyl group, a 2-methyl-2-propynyl group, a 1-butenyl group, a 2-butenyl group, a 3-butenyl group, a 1-butynyl group, a 2-butynyl group, and/or a 3-butynyl group.

As utilized herein, “aryl group” may refer to a substituent, in which all atoms in the cyclic substituent have a p-orbital, and these p-orbitals may be conjugated and may include a monocyclic or fused ring polycyclic functional group (for example, rings sharing adjacent pairs of carbon atoms).

As utilized herein, “heteroaryl group” may refer to an aryl group including at least one heteroatom selected from among nitrogen (N), oxygen (O), sulfur (S), phosphorus (P), and/or silicon (Si). Two or more heteroaryl groups may be linked by a sigma bond directly, or if (e.g., when) the heteroaryl group includes two or more rings, the two or more rings may be fused. In one or more embodiments, if (e.g., when) the heteroaryl group is a fused ring, each ring may include one to three heteroatoms.

As utilized herein, unless otherwise defined, “alkenyl group” may refer to an aliphatic unsaturated alkenyl group including at least one double bond as a linear and/or branched aliphatic hydrocarbon group.

As utilized herein, unless otherwise defined, “alkynyl group” may refer to an aliphatic unsaturated alkynyl group including at least one triple bond as a linear and/or branched aliphatic hydrocarbon group.

Hereinafter, a semiconductor photoresist composition according to one or more embodiments is described.

In one or more embodiments, the semiconductor photoresist composition may include a Sn-containing organometallic compound, a carboxylic acid compound substituted with an oxygen (O)-containing heterocycle, and a solvent.

In one or more embodiments, the semiconductor photoresist composition may include a carboxylic acid compound substituted with an O-containing heterocycle, thereby improving sensitivity and LER and realizing excellent or suitable resolution. That is, in one or more embodiments, the semiconductor photoresist composition includes a tin-containing organometallic compound and a carboxylic acid compound with an oxygen-containing heterocycle, which together enhance sensitivity and line edge roughness while achieving excellent resolution.

The carboxylic acid compound substituted with the O-containing heterocycle may be represented by Chemical Formula 1.

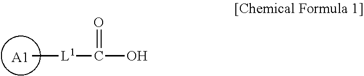

In Chemical Formula 1,
A1 may be an O-containing heterocycle,
L¹ may be a single bond, a substituted or unsubstituted C1 to C10 alkylene group, a substituted or unsubstituted C2 to C10 alkenylene group, a substituted or unsubstituted C2 to C10 alkynylene group, and/or a substituted or unsubstituted C6 to C20 arylene group.

The O-containing heterocycle may be substituted or unsubstituted furan, substituted or unsubstituted tetrahydrofuran, substituted or unsubstituted pyran, substituted or unsubstituted dihydropyran, substituted or unsubstituted maleic anhydride, substituted or unsubstituted succinic anhydride, substituted or unsubstituted butyrolactone, and/or a (e.g., any suitable) combination thereof.

As an example, the carboxylic acid compound substituted with the O-containing heterocycle may be represented by any one of (e.g., selected from among) Chemical Formula 1-1 to Chemical Formula 1-7.

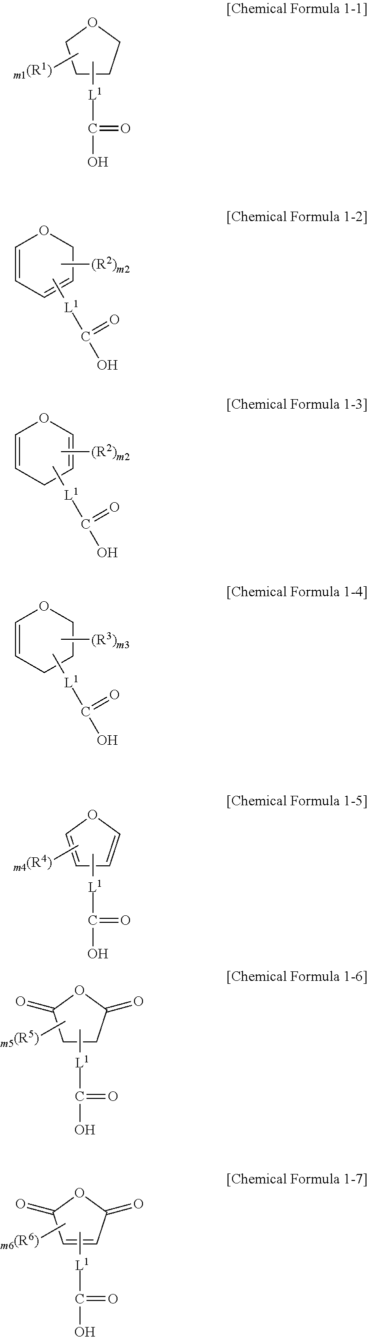

In Chemical Formula 1-1 to Chemical Formula 1-7,
R¹ to R⁶ may each independently be hydrogen, halogen, a hydroxyl group, a substituted or unsubstituted C1 to C20 alkyl group, a substituted or unsubstituted C6 to C30 aryl group, and/or a (e.g., any suitable) combination thereof.

L¹ may be a single bond, a substituted or unsubstituted C1 to C10 alkylene group, a substituted or unsubstituted C2 to C10 alkenylene group, a substituted or unsubstituted C2 to C10 alkynylene group, and/or a substituted or unsubstituted C6 to C20 arylene group.

m1 and m3 may each independently be one of integers of 1 to 7, m2 may be one of integers of 1 to 5, m4 and m5 may each independently be one of integers of 1 to 3, and m6 is 1.

When m1 is 2 or more, each R¹ may be the same or different from each other.

When m2 is 2 or more, each R² may be the same or different from each other.

When m3 is 2 or more, each R³ may be the same or different from each other.

When m4 is 2 or more, each R⁴ may be the same or different from each other.

When m5 is 2 or more, each R⁵ may be the same or different from each other.

When m6 is 2 or more, each R⁶ may be the same or different from each other.

In some embodiments, the carboxylic acid compound substituted with the O-containing heterocycle may be any one selected from among the compounds listed in Group 1.

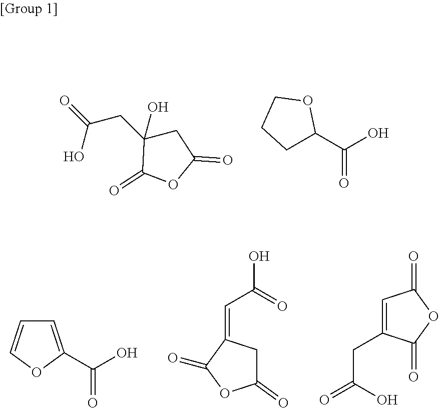

The carboxylic acid compound substituted with an O-containing heterocycle may be included in an amount of about 0.001 to about 10 wt % based on 100 wt % of a total weight of the semiconductor photoresist composition.

For example, the carboxylic acid compound substituted with the O-containing heterocycle may be included in an amount of about 0.01 to about 10 wt %, about 0.01 to about 5 wt %, about 0.05 to about 5 wt %, or about 0.1 to about 5 wt % based on 100 wt % of a total weight of the semiconductor photoresist composition.

The Sn-containing organometallic compound may be included in an amount of about 0.5 wt % to about 30 wt % based on 100 wt % of a total weight of the semiconductor photoresist composition.

In one or more embodiments, the semiconductor photoresist composition may improve the sensitivity of the photoresist by including the Sn-containing organometallic compound and the carboxylic acid compound substituted with the O-containing heterocycle within the above content (e.g., amount) ranges.

In one or more embodiments, the semiconductor photoresist composition may include the Sn-containing organometallic compound and the carboxylic acid compound substituted with the O-containing heterocycle in a weight ratio of about 99:1 to about 60:40. For example, the semiconductor photoresist composition may include the Sn-containing organometallic compound and the carboxylic acid compound substituted with the O-containing heterocycle in a weight ratio of about 90:10 to about 60:40.

If (e.g., when) the weight ratio of the Sn-containing organometallic compound and the carboxylic acid compound satisfies the above range, a semiconductor photoresist composition having excellent or suitable sensitivity may be provided.

In one or more embodiments, the Sn-containing organometallic compound may include at least one of an organic oxy group and/or an organic carbonyloxy group.

The Sn-containing organometallic compound may be represented by Chemical Formula 2.

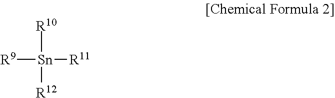

In Chemical Formula 2,

R⁹ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a substituted or unsubstituted C6 to C30 arylalkyl group.

R¹⁰ to R¹² may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, an alkoxy or aryloxy group (e.g., —OR^{a}, where R^{a} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), a carboxyl group (e.g., —O(CO)R^{b}, where R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylamido or dialkylamido group (e.g., —NR^{c}R^{d}, where R^{c} and R^{d} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidato group (e.g., —NR^{e}(COR^{f}), where R^{e} and R^{f} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidinato group (e.g., —NR^{g}C(NR^{h})Rⁱ, where R^{g}, R^{h}, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylthio or arylthiol group (e.g., —SRI, where Rⁱ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof) or a thiocarboxyl group (e.g., —S(CO)R^{k}, where R^{k} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof).

At least one of R¹⁰ to R¹² may be selected from among an alkoxy or aryloxy group (e.g., —OR^{a}, where R^{a} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), a carboxyl group (e.g., —O(CO)R^{b}, where R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylamido or dialkylamido group (e.g., —NR^{c}R^{d}, where R^{c} and R^{d} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidato group (e.g., —NR^{e}(COR^{f}), where R^{e} and R^{f} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidinato group (e.g., —NR^{g}C(NR^{h})Rⁱ, where R^{g}, R^{h}, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylthio or arylthiol group (e.g., —SRI, where Rⁱ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), and a thiocarboxyl group (e.g., —S(CO)R^{k}, where R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof).

At least one of R¹⁰ to R¹² may be selected from among an alkoxy or aryloxy group (e.g., —OR^{a}, where R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), and a carboxyl group (e.g., —O(CO)R^{b}, where R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof).

In one or more embodiments, the compound represented by Chemical Formula 2 may include —OR^{a} and/or —OC(═O)R^{b} as a ligand, so that a pattern formed utilizing a semiconductor photoresist composition including the compound represented by Chemical Formula 2 which includes —OR^{a} and/or —OC(═O)R^{b} as a ligand may exhibit excellent or suitable limiting resolution.

Additionally, the —OR^{a} and/or —OC(═O)R^{b} ligand may determine the solubility of the compound represented by Chemical Formula 2 in a solvent.

R⁹ may be a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds and/or triple bonds, a substituted or unsubstituted C6 to C20 aryl group, a substituted or unsubstituted C4 to C20 heteroaryl group, a carbonyl group, an ethoxy group, a propoxy group, and/or a (e.g., any suitable) combination thereof,
R^{a} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, and/or a (e.g., any suitable) combination thereof.

R^{b} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, and/or a (e.g., any suitable) combination thereof.

R⁹ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, and/or a (e.g., any suitable) combination thereof.

R^{a} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, and/or a (e.g., any suitable) combination thereof.

R^{b} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, butenyl group, ethynyl group, propynyl group, butynyl group, phenyl group, tolyl group, xylene group, benzyl group, and/or a (e.g., any suitable) combination thereof.

Additionally, the Sn-containing organometallic compound may be represented by Chemical Formula 3 or Chemical Formula 4.

R¹²_{z}SnO_{(2-(z/2)-(x/2))}(OH)x [Chemical Formula 3]

In Chemical Formula 3,
R¹² may be a C1 to C31 hydrocarbyl group, 0<z≤2, and 0<(z+x)≤4;

R¹³ₐ₁Sn_{b1}X_{c1}Y_{d1} [Chemical Formula 4]

In Chemical Formula 4,
R¹³ may be a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, and/or a (e.g., any suitable) combination thereof.

X may be sulfur (S), selenium (Se), and/or tellurium (Te).

Y may be —OR^{l} and/or —OC(═O)R^{m}, where R^{l} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof.

R^{m} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof.

a1, b1, c1, and d1 may each independently be an integer of 1 to 20.

In one or more embodiments, the solvent of the semiconductor photoresist composition be an organic solvent, and may be for example aromatic compounds (e.g., xylene, toluene, and/or the like), alcohols (e.g., 4-methyl-2-pentanol, 4-methyl-2-propanol, 1-butanol, methanol, isopropyl alcohol, and/or 1-propanol), ethers (e.g., anisole, tetrahydrofuran), esters (e.g., n-butyl acetate, propylene glycol monomethyl ether acetate, ethyl acetate, and/or ethyl lactate), ketones (e.g., methyl ethyl ketone, and/or 2-heptanone), and/or a (e.g., any suitable)mixture thereof, but the present disclosure is not limited thereto.

In one or more embodiments, the semiconductor photoresist composition may further include a resin in addition to the aforementioned Sn-containing organometallic compound, carboxylic acid compound, and/or solvent.

The resin may be a phenolic resin including at least one (e.g., may be any one) aromatic moiety of (e.g., selected from among) moieties of Group 2.

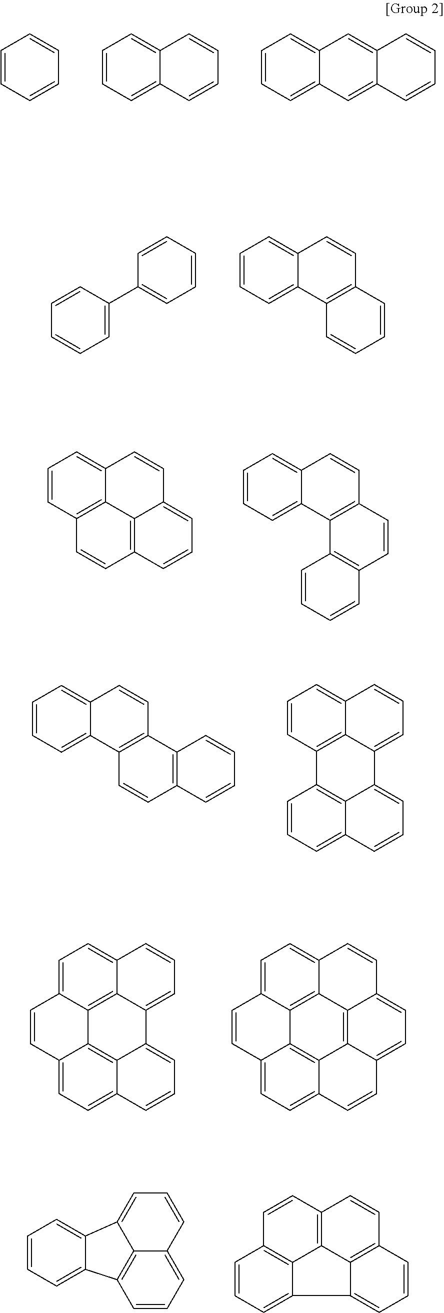

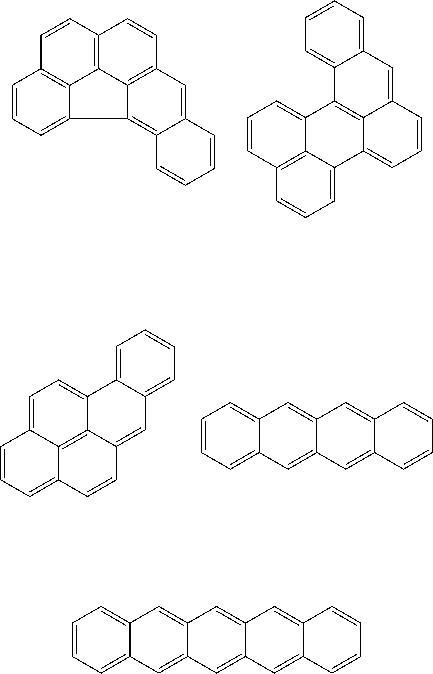

In one or more embodiments, the resin may have a weight average molecular weight of about 500 to about 20,000.

In one or more embodiments, the resin may be included in an amount of about 0.1 wt % to about 50 wt % based on 100 wt % of a total amount of the semiconductor photoresist composition.

If (e.g., when) the resin is included in the above content (e.g., amount) range, the semiconductor photoresist composition may have excellent or suitable etch resistance and heat resistance.

In one or more embodiments, in contrast, the semiconductor photoresist composition may include (e.g., consist of) the aforementioned Sn-containing organometallic compound, carboxylic acid compound, solvent, and/or resin.

In some embodiments, the semiconductor photoresist composition may further include additives as needed. Examples of the additives may be a surfactant, a crosslinking agent, a leveling agent, an organic acid, a quencher, and/or a (e.g., any suitable) combination thereof.

The surfactant may include, for example, an alkyl benzene sulfonate salt, an alkyl pyridinium salt, polyethylene glycol, a quaternary ammonium salt, and/or a (e.g., any suitable) combination thereof, but the present disclosure is not limited thereto.

The crosslinking agent may be, for example, a melamine-based crosslinking agent, a substituted urea-based crosslinking agent, an acryl-based crosslinking agent, an epoxy-based crosslinking agent, and/or a polymer-based crosslinking agent, but the present disclosure is not limited thereto. It may be a crosslinking agent having at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be utilized for improving coating flatness during printing and may be a commercially available suitable leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, and/or a (e.g., any suitable) combination thereof, but the present disclosure is not limited thereto.

The quencher may be diphenyl (p-tolyl) amine, methyl diphenyl amine, triphenyl amine, phenylenediamine, naphthylamine, diaminonaphthalene, and/or a (e.g., any suitable) combination thereof.

A use amount of the additives may be controlled or selected depending on desired or suitable properties.

In addition, the semiconductor photoresist composition may further include a silane coupling agent as an adherence enhancer, in order to improve a close-contacting force with the substrate (e.g., in order to improve adherence of the semiconductor photoresist composition to the substrate). The silane coupling agent may be, for example, a silane compound including a carbon-carbon unsaturated bond such as vinyltrimethoxysilane, vinyl triethoxysilane, vinyl trichlorosilane, vinyl tris(β-methoxyethoxy)silane; or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy[3-(phenylamino)propyl]silane, and/or the like, but the present disclosure is not limited thereto.

The semiconductor photoresist composition may be formed into a pattern having a high aspect ratio without a collapse. In one or more embodiments, in order to form a fine pattern having a width (e.g., a line width) of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, or for example, about 5 nm to about 20 nm, the semiconductor photoresist composition may be utilized for a photoresist process utilizing light in a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, in one or more embodiments, the semiconductor photoresist composition may be utilized to realize extreme ultraviolet lithography utilizing an EUV light source of a wavelength of about 13.5 nm.

In one or more embodiments, a method of forming patterns utilizing the aforementioned semiconductor photoresist composition may be provided. For example, the manufactured pattern may be a photoresist pattern.

In one or more embodiments, the method of forming patterns may include forming an etching-objective layer on a substrate, coating the semiconductor photoresist composition on the etching-objective layer to form a photoresist layer, patterning the photoresist layer to form a photoresist pattern, and etching the etching-objective layer utilizing the photoresist pattern as an etching mask.

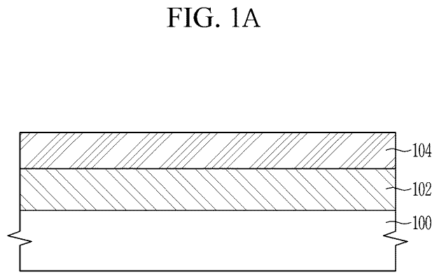

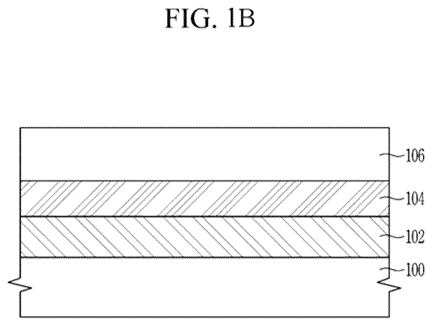

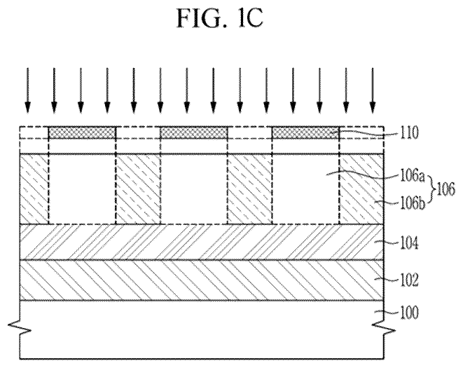

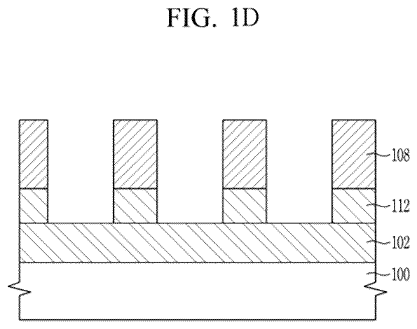

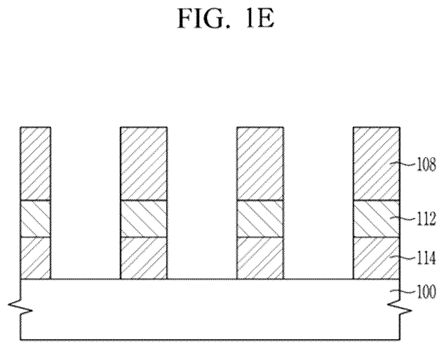

Hereinafter, a method of forming patterns using the semiconductor photoresist composition is described referring to FIGS. 1A-1E. FIGS. 1A-1E are cross-sectional views for illustrating a method of forming patterns using a semiconductor photoresist composition according to one or more embodiments.

Referring to FIG. 1A, an object for etching (e.g., etching-objective layer or etching-target layer) may be prepared. The aspect for etching may be a thin film 102 formed on a semiconductor substrate 100. Hereinafter, the object for etching may be limited to the thin film 102. A surface of the thin film 102 is washed to remove impurities and/or the like remaining thereon. The thin film 102 may be for example a silicon nitride layer, a polysilicon layer, and/or a silicon oxide layer.

Subsequently, the resist underlayer composition for forming a resist underlayer 104 is spin-coated on the surface of the washed thin film 102. However, one or more embodiments are not limited thereto, and suitable one or more suitable coating methods, for example a spray coating, a dip coating, a knife edge coating, a printing method, for example, an inkjet printing and a screen printing, and/or the like may be utilized.

The coating process of the resist underlayer may not be provided, and hereinafter, a process including a coating of the resist underlayer is described.

Then, the coated composition is dried and baked to form a resist underlayer 104 on the thin film 102. The baking may be performed at about 100° C. to about 500° C., for example, about 100° C. to about 300° C.

The resist underlayer 104 is formed between the substrate 100 and a photoresist layer 106 and thus may prevent or reduce non-uniformity and pattern formability of a photoresist line width when a ray reflected from on the interface between the substrate 100 and the photoresist layer 106 or a hardmask between layers is scattered into an unintended photoresist region.

Referring to FIG. 1B, the photoresist layer 106 is formed by coating the semiconductor photoresist composition on the resist underlayer 104. The photoresist layer 106 is obtained by coating the aforementioned semiconductor photoresist composition on the thin film 102 formed on the substrate 100 and then, curing the semiconductor photoresist composition through a heat treatment.

More specifically, the formation of a pattern by utilizing the semiconductor photoresist composition may include coating the semiconductor resist composition on the substrate 100 having the thin film 102 through spin coating, slit coating, inkjet printing, and/or the like and then, drying the semiconductor resist composition to form the photoresist layer 106.

The semiconductor photoresist composition has already been illustrated in more detail and will not be illustrated again.

Subsequently, a substrate 100 having the photoresist layer 106 is subjected to a first baking process (e.g., thermal treatment). The first baking process may be performed at about 80° C. to about 120° C.

Referring to FIG. 1C, the photoresist layer 106 may be selectively exposed utilizing a patterned mask 110.

For example, the exposure may utilize an activation radiation with light having a high energy wavelength such as EUV (e.g., extreme ultraviolet having a wavelength of about 13.5 nm), an E-Beam (e.g., an electron beam), and/or the like as well as light having a wavelength such as an i-line (e.g., a wavelength of about 365 nm), a KrF excimer laser (e.g., a wavelength of about 248 nm), an ArF excimer laser (a wavelength of about 193 nm), and/or the like.

More specifically, in one or more embodiments, light or exposure beam for the exposure may have a wavelength in a range of about 5 nm to about 150 nm and/or a high energy wavelength, for example, may be an EUV (e.g., extreme ultraviolet having a wavelength of 13.5 nm), and/or may be an E-Beam (an electron beam), and/or the like.

The exposed region 106b of the photoresist layer 106 has a different solubility from the unexposed region 106a of the photoresist layer 106 by forming a polymer by a crosslinking reaction, such as a condensation between organometallic compounds.

Subsequently, the substrate 100 is subjected to a second baking process (e.g., thermal treatment). The second baking process may be performed at a temperature of about 90° C. to about 200° C. The exposed region 106b of the photoresist layer 106 becomes easily indissoluble regarding a developer due to the second baking process.

In FIG. 1D, the unexposed region 106a of the photoresist layer is dissolved and removed utilizing the developer to form a photoresist pattern 108. For example, the unexposed region 106a of the photoresist layer is dissolved and removed by utilizing an organic solvent, such as 2-heptanone and/or the like, to complete the photoresist pattern 108 corresponding to the negative tone image.

As described above, in one or more embodiments, a developer utilized in a method of forming patterns may be an organic solvent. In one or more embodiments, the organic solvent utilized in the method of forming patterns may be, for example, ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, and/or a (e.g., any suitable) combination thereof.

However, in one or more embodiments, the photoresist pattern may not be necessarily limited to the negative tone image but may be formed to have a positive tone image. Herein, a developer utilized for forming the positive tone image may be a quaternary ammonium hydroxide composition, such as tetraethylammonium hydroxide, tetrapropylammonium hydroxide, tetrabutylammonium hydroxide, and/or a (e.g., any suitable) combination thereof.

As described above, exposure to light having a high energy such as EUV (e.g., extreme ultraviolet having a wavelength of 13.5 nm), an E-Beam (e.g., an electron beam), and/or the like as well as light having a wavelength such as i-line (wavelength of about 365 nm), KrF excimer laser (wavelength of about 248 nm), ArF excimer laser (wavelength of about 193 nm), and/or the like may provide a photoresist pattern 108 having a thickness (e.g., a width of a thickness) of about 5 nm to about 100 nm. In other words, the application of high-energy light/beam source(s) such as EUV (Extreme Ultraviolet with a wavelength of 13.5 nm) and/or E-Beam (Electron Beam), and/or with other light sources like i-line (365 nm), KrF excimer laser (248 nm), and/or ArF excimer laser (193 nm), may result in the formation of the photoresist pattern 108. This pattern can exhibit a range of thicknesses, typically from about 5 nm to about 100 nm. For example, the photoresist pattern 108 may have a thickness (e.g., a width of a thickness) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In addition, the photoresist pattern 108 may have a pitch having (width) a half-pitch of less than or equal to about 50 nm, for example, less than or equal to about 40 nm, for example, less than or equal to about 30 nm, for example, less than or equal to about 20 nm, or for example, less than or equal to about 15 nm, and a line width roughness of less than or equal to about 10 nm, or less than or equal to about 5 nm, less than or equal to about 3 nm, or less than or equal to about 2 nm.

Subsequently, the photoresist pattern 108 is utilized as an etching mask to etch the resist underlayer 104. Through this etching process, an organic layer pattern 112 is formed. The organic layer pattern 112 also may have a width corresponding to that of the photoresist pattern 108.

Referring to FIG. 1E, the exposed thin film 102 is etched by applying the photoresist pattern 108 as an etching mask. As a result, the thin film is formed as a thin film pattern 114.

The etching of the thin film 102 may be, for example, dry etching utilizing an etching gas and the etching gas may be for example CHF₃, CF₄, Cl₂, BCl₃ or a (e.g., any suitable) mixed gas thereof.

In the exposure process, the thin film pattern 114 formed by utilizing the photoresist pattern 108 formed through the exposure process performed by utilizing an EUV light source may have a width (e.g., line width) corresponding to a width of the photoresist pattern 108. For example, the thin film pattern 114 may have a width (e.g., line width) of about 5 nm to about 100 nm which may be equal to the width of the photoresist pattern 108. For example, the thin film pattern 114 formed by utilizing the photoresist pattern 108 formed through the exposure process performed by utilizing an EUV light source may have a width (e.g., a line width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and more specifically a width of less than or equal to about 20 nm, like the width of the photoresist pattern 108.

Hereinafter, disclosure will be described in more detail through examples of the preparation of the aforementioned semiconductor photoresist composition. However, disclosure is technically not restricted by the following examples.

### Synthesis of Organometallic Compound

### Synthesis Example 1

40.7 g of t-butylSnPh₃ and 300 g of propionic acid were added to a 250 mL two-neck round bottom flask and were heated and refluxed for 24 hours.

By removing unreacted propionic acid under a reduced pressure, a compound represented by Chemical Formula 5 was obtained.

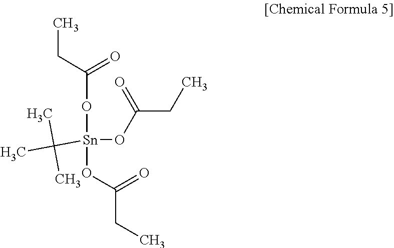 [SMILES: CCC(=O)[O][Sn]([O]C(=O)CC)([O]C(=O)CC)[C](C)(C)C]

### Synthesis Example 2

30 mL of anhydrous pentane was added to 10 g of t-AmylSnCl₃, the temperature was maintained at 0° C., then 7.4 g of diethyl amine and 6.1 g of ethanol were added thereto, and stirred at room temperature for 1 hour. When the reaction was completed, filtration, concentration, and drying under vacuum were performed to obtain a compound represented by Chemical Formula 6.

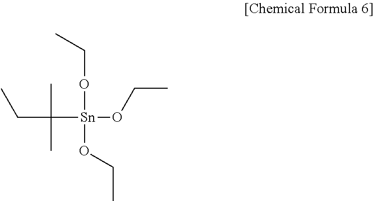

### Synthesis Example 3

10 g of dibutyltin dichloride was dissolved 30 mL of ether, 70 mL of a 1 M sodium hydroxide (NaOH) aqueous solution was added thereto and then, stirred for 1 hour. After the stirring, a solid produced therein was filtered, three times washed with 25 mL of deionized water, and dried at 100° C. under a reduced pressure to obtain an organometallic compound represented by Chemical Formula 7 and having a weight average molecular weight of 1,500.

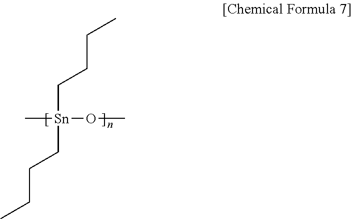

### Preparation of Semiconductor Photoresist Compositions

### Examples 1 to 18, and Comparative Examples 1 to 3

The Sn-containing organometallic compounds represented by Chemical Formulae 5 to 7 obtained in Synthesis Examples 1 to 3 and carboxylic acid compounds represented by A1 to A5 were mixed with propylene glycol methyl ether acetate (PGMEA) in the weight ratios shown in Table 1 and were dissolved at a concentration of 3 wt % and filtered through a 0.1 μm polytetrafluoroethylene PTFE) syringe filter to prepare compositions for semiconductor photoresists according to Examples 1 to 18 and Comparative Examples 1 to 3.

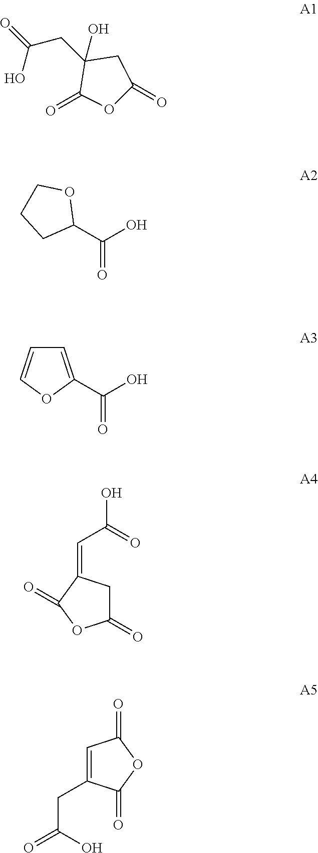 [SMILES: O=C(O)CC1(O)CC(=O)OC1=O ; O=C(O)C1CCCO1 ; O=C(O)c1ccco1 ; O=C(O)/C=C1\CC(=O)OC1=O ; O=C(O)CC1=CC(=O)OC1=O]

TABLE 1

| | Organometallic | Carboxylic Acid |
|---|---|---|
| | compound (wt %) | compound (wt %) |
| Comparative | Chemical Formula 5 | — |
| Example 1 | (3.00) | |
| Example 1 | Chemical Formula 5 | A1 |
| | (2.5) | (0.5) |
| Example 2 | Chemical Formula 5 | A1 |
| | (2.0) | (1.0) |
| Example 3 | Chemical Formula 5 | A2 |
| | (2.0) | (1.0) |
| Example 4 | Chemical Formula 5 | A3 |
| | (2.0) | (1.0) |
| Example 5 | Chemical Formula 5 | A4 |
| | (2.0) | (1.0) |
| Example 6 | Chemical Formula 5 | A5 |
| | (2.0) | (1.0) |
| Comparative | Chemical Formula 6 | — |
| Example 2 | (3.0) | |
| Example 7 | Chemical Formula 6 | A1 |
| | (2.5) | (0.5) |
| Example 8 | Chemical Formula 6 | A1 |
| | (2.0) | (1.0) |
| Example 9 | Chemical Formula 6 | A2 |
| | (2.0) | (1.0) |
| Example 10 | Chemical Formula 6 | A3 |
| | (2.0) | (1.0) |
| Example 11 | Chemical Formula 6 | A4 |
| | (2.0) | (1.0) |
| Example 12 | Chemical Formula 6 | A5 |
| | (2.0) | (1.0) |
| Comparative | Chemical Formula 7 | — |
| Example 3 | (3.0) | |
| Example 13 | Chemical Formula 7 | A1 |
| | (2.5) | (0.5) |
| Example 14 | Chemical Formula 7 | A1 |
| | (2.0) | (1.0) |
| Example 15 | Chemical Formula 7 | A2 |
| | (2.0) | (1.0) |
| Example 16 | Chemical Formula 7 | A3 |
| | (2.0) | (1.0) |
| Example 17 | Chemical Formula 7 | A4 |
| | (2.0) | (1.0) |
| Example 18 | Chemical Formula 7 | A5 |
| | (2.0) | (1.0) |

### Evaluation 1: Evaluation of Sensitivity and Line Edge Roughness (LER)

Each of the photoresist compositions according to Examples 1 to 18 and Comparative Examples 1 to 3 was spin-coated at 1500 rpm for 30 seconds on a 200 mm circular silicon wafer of which the surface was deposited with HMDS, baked at 110° C. for 60 seconds (e.g., post-apply baked (PAB)), and then, allowed to stand at room temperature (23±2° C.) for 30 seconds.

Subsequently, a linear array of 50 circular pads with a diameter of 500 μm was projected onto the wafer coated with each of the photoresist compositions by utilizing EUV light (Lawrence Berkeley National Laboratory Micro Exposure Tool, MET). Herein, pad exposure time was adjusted to ensure that increased EUV dose was applied to each pad.

Then, the resist and the substrate were baked at 160° C. for 120 seconds on a hot plate after the exposure. The baked film was developed in a PGMEA solvent to form a negative tone image. Finally, the obtained film was baked again at 150° C. for 2 minutes on the hot plate to complete the process.

The residual resist thickness of the exposed pad was measured utilizing an ellipsometer. The remaining thickness for each exposure dose was measured and graphed as a function of the exposure dose to measure sensitivity and LER was measured from Field Emission Scanning Electron Microscopes (FE-SEM) images.

Sensitivity and line edge roughness were evaluated according to the following criteria, and the results are shown in Tables 2 to 4.

### [Evaluation Criteria for Sensitivity]

A: less than 50 mJ/cm²
B: greater than or equal to 50 mJ/cm²

### [Evaluation Criteria for LER]

∘: less than or equal to 2 nm
Δ: greater than 2 nm and less than or equal to 5 nm
X: greater than 5 nm

### Evaluation 2: Evaluation of Resolution

After completing the process, a line/space critical dimension (CD) pattern was formed on the pattern wafer, which was then transferred to CD-SEM measurement equipment (GC-9380, Hitachi) to measure the CD size of the area where the half-pitch of the mask pattern is 14 nm, and the minimum value among space CDs, which is the distance between lines, are shown in Tables 2 to 4.

TABLE 2

| | | | Minimum Space |
|---|---|---|---|
| | Sensitivity | LER | CD (@14 nm) |
| Comparative | A | X | 13.8 |
| Example 1 | | | |
| Example 1 | A | ◯ | 12.1 |
| Example 2 | A | ◯ | 11.0 |
| Example 3 | A | ◯ | 12.8 |
| Example 4 | A | ◯ | 13.2 |
| Example 5 | A | Δ | 13.2 |
| Example 6 | A | Δ | 13.5 |

TABLE 3

| | | | Minimum Space |
|---|---|---|---|
| | Sensitivity | LER | CD (@14 nm) |
| Comparative | B | X | 14.5 |
| Example 2 | | | |
| Example 7 | A | Δ | 12.5 |
| Example 8 | A | ◯ | 12.2 |
| Example 9 | B | Δ | 13.4 |
| Example 10 | B | Δ | 14.1 |
| Example 11 | B | Δ | 14.0 |
| Example 12 | B | Δ | 14.2 |

TABLE 4

| | | | Minimum Space |
|---|---|---|---|
| | Sensitivity | LER | CD (@14 nm) |
| Comparative | B | X | 14.4 |
| Example 3 | | | |
| Example 13 | A | Δ | 13.5 |
| Example 14 | A | Δ | 13.2 |
| Example 15 | B | Δ | 13.8 |
| Example 16 | B | Δ | 13.8 |
| Example 17 | B | Δ | 13.9 |
| Example 18 | B | Δ | 14.1 |

From the results in Tables 2 to 4, the patterns formed utilizing the semiconductor photoresist compositions according to Examples 1 to 18 each exhibited superior sensitivity, LER, and resolution characteristics compared to Comparative Examples 1 to 3.

As utilized herein, the terms “and/or” and “or” may include any and all combinations of one or more of the associated listed items. Expressions such as “at least one of,” when preceding a list of elements, modify the entire list of elements and do not modify the individual elements of the list.

It will be further understood that the terms “comprise”, “include,” or “have/has,” when utilized in the present disclosure, specify the presence of stated features, integers, steps, operations, elements, and/or components, but do not preclude the presence or addition of one or more other features, integers, steps, operations, elements, components, and/or groups thereof. The “/” utilized below may be interpreted as “and” or as “or” depending on the situation.

As utilized herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure”.

In the context of the present disclosure and unless otherwise defined, the terms “use,” “using,” and “used” may be considered synonymous with the terms “utilize,” “utilizing,” and “utilized,” respectively.

As utilized herein, the term “about,” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

A pattern forming device, a semiconductor forming device and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Hereinbefore, the certain embodiments have been described and illustrated, however, it is apparent to a person with ordinary skill in the art that disclosure is not limited to one or more embodiments as described, and may be variously modified and transformed without departing from the spirit and scope of disclosure. Accordingly, the modified or transformed embodiments as such may not be understood separately from the technical ideas and aspects of disclosure, and the modified embodiments are within the scope of the claims of disclosure.

### REFERENCE NUMERALS

| | |
|---|---|
| 100: substrate | 102: thin film |
| 104: resist underlayer | 106: photoresist layer |
| 106a: unexposed region | 106b: exposed region |
| 108: photoresist pattern | 112: organic layer pattern |
| 110: patterned mask | 114: thin film pattern |

What is claimed is:

1. A semiconductor photoresist composition, comprising:
a tin (Sn)-containing organometallic compound;
a carboxylic acid compound substituted with an oxygen (O-containing heterocycle; and
a solvent.

2. The semiconductor photoresist composition as claimed in claim 1, wherein the carboxylic acid compound substituted with the O-containing heterocycle is represented by Chemical Formula 1: 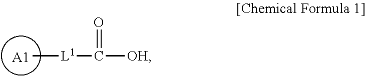
in Chemical Formula 1,
A1 being an O-containing heterocycle, and
L¹ being a single bond, a substituted or unsubstituted C1 to C10 alkylene group, a substituted or unsubstituted C2 to C10 alkenylene group, a substituted or unsubstituted C2 to C10 alkynylene group, or a substituted or unsubstituted C6 to C20 arylene group.

3. The semiconductor photoresist composition as claimed in claim 1, wherein the O-containing heterocycle is substituted or unsubstituted furan, substituted or unsubstituted tetrahydrofuran, substituted or unsubstituted pyran, substituted or unsubstituted dihydropyran, substituted or unsubstituted maleic anhydride, substituted or unsubstituted succinic anhydride, substituted or unsubstituted butyrolactone, or a combination thereof.

4. The semiconductor photoresist composition as claimed in claim 1, wherein the carboxylic acid compound substituted with the O-containing heterocycle is represented by any one of Chemical Formula 1-1 to Chemical Formula 1-7: 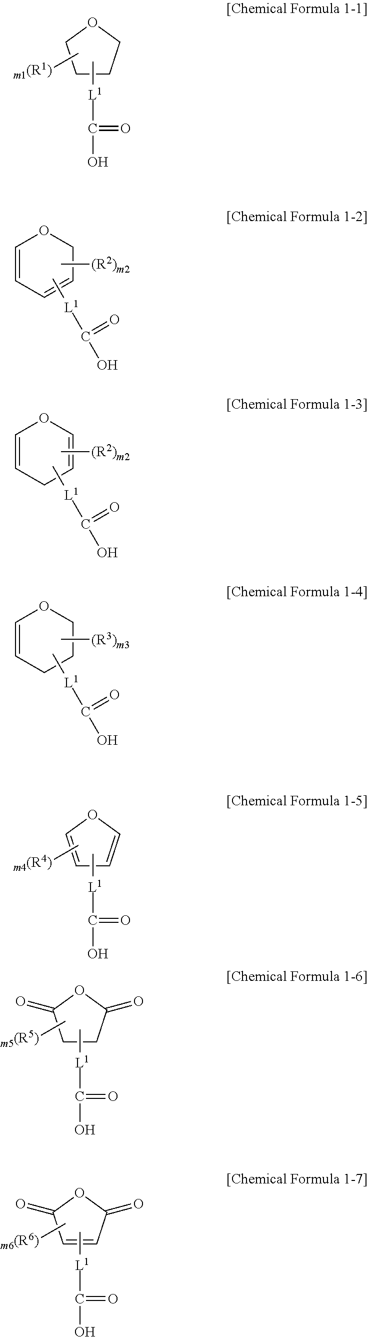
in Chemical Formula 1-1 to Chemical Formula 1-7,
R¹ to R⁶ being each independently hydrogen, halogen, a hydroxy group, a substituted or unsubstituted C1 to C20 alkyl group, a substituted or unsubstituted C6 to C30 aryl group, or a combination thereof,
L¹ being a single bond, a substituted or unsubstituted C1 to C10 alkylene group, a substituted or unsubstituted C2 to C10 alkenylene group, a substituted or unsubstituted C2 to C10 alkynylene group, or a substituted or unsubstituted C6 to C20 arylene group,
m1 and m3 being each independently one of integers of 1 to 7,
m2 being one of integers of 1 to 5,
m4 and m5 being each independently one of integers of 1 to 3, and
m6 being 1.

5. The semiconductor photoresist composition as claimed in claim 1, wherein the carboxylic acid compound substituted with the O-containing heterocycle is any one selected from among the compounds listed in Group 1:

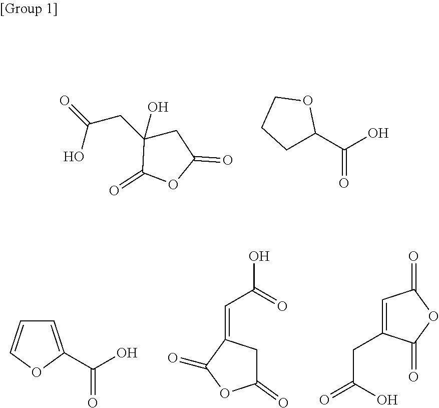

6. The semiconductor photoresist composition as claimed in claim 1, wherein the carboxylic acid compound substituted with the O-containing heterocycle is in an amount of about 0.001 to about 10 wt % based on 100 wt % of a total weight of the semiconductor photoresist composition.

7. The semiconductor photoresist composition as claimed in claim 1, wherein the carboxylic acid compound substituted with the O-containing heterocycle is in an amount of about 0.1 to about 5 wt % based on 100 wt % of a total weight of the semiconductor photoresist composition.

8. The semiconductor photoresist composition as claimed in claim 1, wherein the Sn-containing organometallic compound is in an amount of about 0.5 wt % to about 30 wt % based on 100 wt % of a total weight of the semiconductor photoresist composition.

9. The semiconductor photoresist composition as claimed in claim 1, wherein the semiconductor photoresist composition further comprises an additive of a surfactant, a crosslinking agent, a leveling agent, an organic acid, a quencher, or a combination thereof.

10. The semiconductor photoresist composition as claimed in claim 1, wherein the Sn-containing organometallic compound comprises at least one of an organic oxy group or an organic carbonyloxy group.

11. The semiconductor photoresist composition as claimed in claim 1, wherein the Sn-containing organometallic compound is represented by Chemical Formula 2: 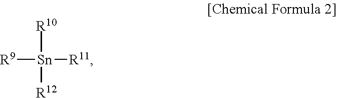
in Chemical Formula 2,
R⁹ being selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C6 to C30 arylalkyl group,
R¹⁰ to R¹² being each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, an alkoxy or aryloxy group, an alkylamido or dialkylamido group, or a thiocarboxyl group,
at least one of R¹⁰ to R¹² is an alkoxy or aryloxy group, a carboxyl group, an alkylamido or dialkylamido group, an amidato group, an amidinato group, an alkylthio or arylthio group, or a thiocarboxyl group.

12. The semiconductor photoresist composition as claimed in claim 11, wherein at least one of R¹⁰ to R¹² is selected from among —OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, or —O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

13. The semiconductor photoresist composition as claimed in claim 12, wherein R⁹ is a substituted or unsubstituted C1 to C8 alkyl group, a substituted or unsubstituted C3 to C8 cycloalkyl group, a substituted or unsubstituted C2 to C8 aliphatic unsaturated organic group comprising one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof,
R^{a} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{b} is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

14. The semiconductor photoresist composition as claimed in claim 1, wherein the Sn-containing organometallic compound is represented by Chemical Formula 3 or Chemical Formula 4:
R¹²_{z}SnO_{(2-(z/2)-(x/2))}(OH)x, [Chemical Formula 3]
in Chemical Formula 3,
R¹² being a C1 to C31 hydrocarbyl group, 0<z≤2, and 0<(z+x)≤4;
R¹³ₐ₁Sn_{b1}X_{c1}Y_{d1}, [Chemical Formula 4]
in Chemical Formula 4,
R¹³ being a substituted or unsubstituted C1 to C20 alkyl group, a substituted or unsubstituted C3 to C20 cycloalkyl group, a substituted or unsubstituted C2 to C20 aliphatic unsaturated organic group comprising one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X being sulfur (S), selenium (Se), or tellurium (Te), and
Y being —OR^{l} or —OC(═O)R^{m}, and
wherein R^{l} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
R^{m} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a1, b1, c1, and d1 are each independently an integer of 1 to 20.

15. A method, comprising:
forming an etching-objective layer on a substrate;
coating the semiconductor photoresist composition as claimed in claim 1 on the etching-objective layer to form a photoresist layer;
patterning the photoresist layer to form a photoresist pattern; and
etching the etching-objective layer utilizing the photoresist pattern as an etching mask,
wherein the method is a method for forming patterns.
